(19) United States
(12) Patent Application Publication
(10) Pub. No.: US 2025/0324520 A1
(43) Pub. Date: Oct. 16, 2025

(54) THIN WIRING MEMBER PRODUCTION METHOD, THIN WIRING MEMBER, AND WIRING BOARD PRODUCTION METHOD

(71) Applicant: Resonac Corporation, Minato-ku, Tokyo (JP)

(72) Inventor: Katsuhiko SUZUKI, Minato-ku, Tokyo (JP)

(21) Appl. No.: 18/857,190

(22) PCT Filed: Oct. 13, 2022
(86) PCT No.: PCT/JP2022/038248

§ 371 Date: Jul. 10, 2025

(51) Int. Cl. H05K 3/46

(52) U.S. Cl. CPC H05K 3/46; H05K 2203/016; H05K 2203/0228; H05K 2203/107; H05K 2203/1453

(57) ABSTRACT

A method for producing a thin wiring member is disclosed. The method includes forming a wiring layer on a first carrier, the wiring layer including a plurality of wiring parts, cutting the wiring layer such that each includes at least one wiring part of the plurality of wiring parts, attaching a second carrier to a second surface on opposite side of a first surface on which the first carrier is provided in the wiring layer, peeling the first carrier from the wiring layer, forming, with laser beam, a modification region to become a starting point of a fracture, in an internal region of the second carrier which corresponds to a site at which the wiring layer has been cut, and expanding the second carrier on which the modification region is formed along a planar direction to divide the second carrier into a plurality of carrier parts.

### TECHNICAL FIELD

The present disclosure relates to a method for producing a thin wiring member, a thin wiring member, and a method for producing a wiring board.

### BACKGROUND ART

Patent Literature 1 discloses an example of a fan-out type semiconductor device. In this semiconductor device, a redistribution layer is provided between a semiconductor chip and external connection terminals, and the terminal interval of the semiconductor chips is widened by the redistribution layer and connected to the external connection terminals.

### CITATION LIST

### Patent Literature

Patent Literature 1: Japanese Unexamined Patent Publication No. 2019-029557

### SUMMARY OF INVENTION

### Technical Problem

In a conventional method, a redistribution layer is formed on the substrate, but it may be difficult to form a fine wiring of the redistribution layer due to a large variation in height of the substrate or the like. Therefore, a method of manufacturing the redistribution layer including fine wiring on a flat glass carrier by patterning and transferring the redistribution layer has been studied. As an example of this method, for example, as illustrated in FIG. 8, a redistribution layer 510 is formed on a first glass carrier 500, and then the second glass carrier 520 is formed on the redistribution layer 510. The redistribution layer 510 is divided by a dicing blade D in a state of being sandwiched between the first glass carrier 500 and the second glass carrier 520. However, in this method, when the second glass carrier 520 is cut by the dicing blade D, a crack C1 may occur in the second glass carrier 520. As a result, the strength may become insufficient and contamination occurs. In addition, chipping C2 may occur in the second glass carrier 520. As a result, not only the problem of insufficient strength as a carrier but also damage or contamination occurs in the wiring layer. By setting the feeding speed when cutting the second glass carrier 520 with the dicing blade D to 1 mm/sec, the occurrence of such cracks C1 or chipping C2 can be prevented. However, in this case, the feeding speed becomes very slow, and the production efficiency of the thin wiring member is significantly deteriorated.

An object of the present disclosure is to provide a method for producing a thin wiring member, a thin wiring member, and a method for producing a wiring board, capable of manufacturing a thin wiring member while preventing occurrence of contamination.

### Solution to Problem

As one aspect, the present disclosure relates to a method for producing a thin wiring member. This production method includes forming a wiring layer on a first carrier, the wiring layer including a plurality of wiring parts corresponding to the plurality of thin wiring members and an insulating part existing around the plurality of wiring parts, cutting the wiring layer such that each includes at least one wiring part of the plurality of wiring parts, attaching a second carrier to a second surface on opposite side of a first surface on which the first carrier is provided in the wiring layer, peeling the first carrier from the wiring layer, forming, with laser beam, a modification region to become a starting point of a fracture, in an internal region of the second carrier which corresponds to a site at which the wiring layer has been cut, and expanding the second carrier on which the modification region is formed along a planar direction to divide the second carrier into a plurality of carrier parts.

This method for producing a thin wiring member includes, apart from cutting the wiring layer, forming, with laser beam, a modification region to become a starting point of a fracture, in an internal region of the second carrier which corresponds to a site at which the wiring layer has been cut, and expanding the second carrier in which the modification region is formed along a planar direction to divide the second carrier into a plurality of carrier parts. In this method, instead of using a dicing blade when dividing the second glass carrier, a fracture starting point is formed by laser beam, and the second glass carrier is fractured from the fracture starting point when expanding. This is laser dicing processing referred to as so-called stealth dicing, and by using such a processing method, it is possible to prevent cracks and chipping from occurring in the divided second glass carrier. This makes it possible to manufacture the thin wiring member while preventing the occurrence of contamination. In addition, according to this method for producing a thin wiring member, since cracks and chipping do not occur when the second glass carrier is divided, decrease in the strength of the glass carrier can be prevented. Furthermore, according to this method for producing a thin wiring member, since cracks and chipping do not occur when the second glass carrier is divided, damage to the wiring part in the thin wiring member can be prevented.

In the above-described method for producing a thin wiring member, the cutting may include cutting the wiring layer with a laser or a dicing blade. The wiring layer to be cut is a member having an unstable shape, which is formed of a thin material having a thickness of, for example, 10 to 50 μm and having adhesiveness or resilience. However, when such a wiring layer is cut, if the cut portion is only a resin, the wiring layer can be accurately cut at a very high speed by using a laser ablation technique. On the other hand, when the metal layer is included in the resin of the cut portion, the wiring layer can be efficiently cut even if the metal layer is included in the resin by using the dicing blade having a wide processing margin.

In the above-described method for a producing thin wiring member, the cutting may be performed in a state where the wiring layer is supported by the first carrier. As described above, the wiring layer to be cut is a member having an unstable shape. However, by cutting the wiring layer in a state of being supported by the first carrier, the wiring layer can be cut with high accuracy.

In the above-described method for producing a thin wiring member, the cutting may include cutting the wiring layer by an ablation laser, and the peeling may include collecting the peeled first carrier for reuse. In this case, it is possible to prevent the first carrier from being damaged or hardly damaged by the cut in the cutting. As a result, according to this production method, the first carrier used for forming the redistribution layer can be reused, and the load on the environment can be reduced.

In the above-described method for producing a thin wiring member, the cutting may be performed after the second carrier is attached to the wiring layer. In this case, it is possible to prevent the first carrier from being damaged by the cut in the cutting. As a result, according to this production method, the first carrier used for forming the redistribution layer can be reused, and the load on the environment can be reduced.

In the above-described method for producing a thin wiring member, the forming of the modification region may be performed after peeling the first carrier. When the wiring layer is cut with a laser or a blade, a processing trace may remain on the installation surface of the first carrier. In this case, if an attempt is made to form the modification region with the laser beam from the first carrier side, an appropriate modification region may not be formed with the laser beam due to this processing trace. Therefore, by forming the modification region in the second carrier after peeling the first carrier, such a manufacturing failure can be prevented, and the modification region can be reliably formed in the second carrier.

In the above-described method for producing a thin wiring member, the forming of the modification region may be performed before peeling the first carrier.

In the above-described method for producing a thin wiring member, the method to peel the first carrier from the wiring layer may be different from the mechanism in which the second carrier or the carrier part is peeled off. In this case, when peeling the first carrier, the second carrier necessary for the subsequent steps can be prevented from being peeled off, and the thin wiring member can be more reliably manufactured. In addition, since the peeling method is different, the first carrier can be easily peeled off.

In the above-described method for producing a thin wiring

member the second carrier may be a glass carrier having a thickness of 0.3 mm to 1.1 mm. In this case, it is possible to increase the degree of freedom of the production method when forming the modification region, and it is easier to execute laser irradiation or the like when peeling the carrier part from the wiring part after using the thin wiring member as a member.

In the above-described method for producing a thin wiring member, the second carrier may be a silicon substrate.

The above-described method for producing a thin wiring member may further include attaching a dicing tape to a surface of the second carrier opposite to a surface to which the wiring layer is attached, and the dividing may include expanding the second carrier by spreading the dicing tape. In this case, the second carrier on which the modification region is formed can be easily divided by a simple means.

The present disclosure relates to a thin wiring member as another aspect. A thin wiring member includes a wiring layer including a wiring and a resin composition present around the wiring or a cured product thereof, and a support layer provided on a surface of the wiring layer, wherein the support layer is a glass carrier. In this case, the thin wiring member can be prevented from being warped or rounded when the wiring board or the semiconductor device is manufactured using the thin wiring member, and the shape thereof can be stabilized.

In the thin wiring member, the thickness of the wiring layer may be less than or equal to 200 μm, the thickness of the support layer may be 0.3 mm to 1.1 mm, and the wiring layer may include wiring having a line width of 5 μm. In this case, a thin wiring member having fine wiring can be provided.

Furthermore, as still another aspect, the present disclosure relates to a method for producing a wiring board. The method for producing a wiring board includes preparing a thin wiring member produced by the method for producing a thin wiring member according to any one of the above, arranging the thin wiring member on a substrate or in a substrate; and connecting the wiring of the thin wiring member to a connection terminal.

### Advantageous Effects of Invention

According to the present disclosure, a thin wiring member can be manufactured while preventing occurrence of contamination.

### BRIEF DESCRIPTION OF DRAWINGS

FIG. 1 is a cross-sectional view illustrating an example of a thin wiring member.

FIG. 2(a) to (d) of FIG. 2 are views sequentially illustrating a method for producing a thin wiring member according to the first embodiment.

FIG. 3(a) to (c) of FIG. 3 are views sequentially illustrating the method for producing a thin wiring member according to the first embodiment, and illustrate steps performed subsequent to the steps in FIG. 2.

FIG. 4(a) to (c) of FIG. 4 are views sequentially illustrating the method for producing a thin wiring member according to the first embodiment, and illustrate steps performed subsequent to the steps in FIG. 3.

FIG. 5(a) to (c) to FIG. 5 are views sequentially illustrating a method for producing a thin wiring member according to a second embodiment.

FIG. 6(a) to (d) to FIG. 6 are views sequentially illustrating a method for producing a thin wiring member according to a third embodiment.

FIG. 7(a) to (d) of FIG. 7 are views sequentially illustrating an example of a method for producing a wiring board using a thin wiring member.

FIG. 8(a) to (c) of FIG. 8 are views sequentially illustrating an example of a method for producing a thin wiring member.

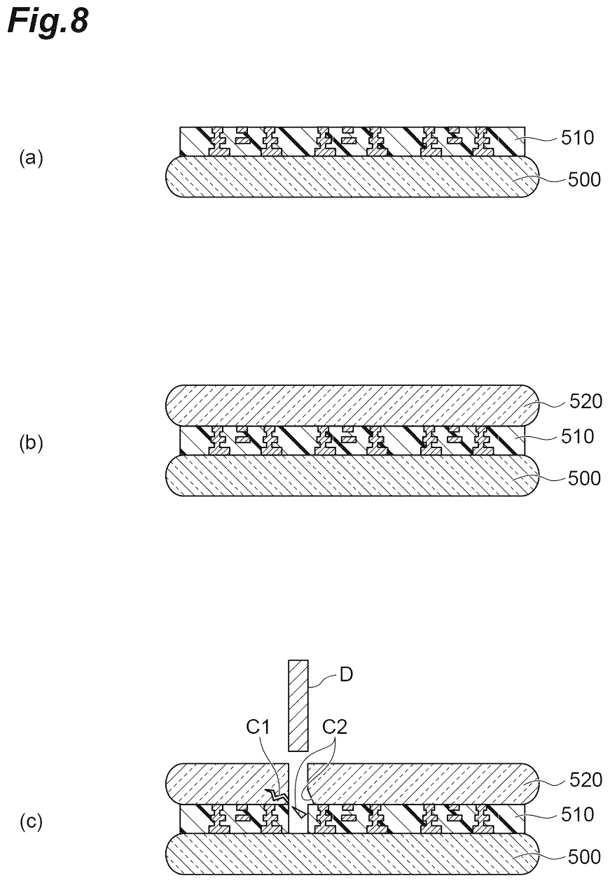

### DESCRIPTION OF EMBODIMENTS

Hereinafter, the present embodiment will be described in detail with reference to the drawings. In the following description, the same or corresponding portions are denoted by the same reference numerals, and redundant description will be omitted. Unless otherwise specified, the positional relationship such as up, down, left, and right is based on the positional relationship illustrated in the drawings. The dimensional ratios in the drawings are not limited to the illustrated ratios.

The use of the terms “left”, “right”, “front”, “back”, “up”, “down”, “upper”, “lower”, “first”, “second”, and the like in the present specification and claims is intended to be descriptive, and does not necessarily mean permanently in this relative position. The term “layer” includes not only a structure having a shape formed on the entire surface but also a structure having a shape formed on a part thereof when observed as a plan view. The term “step” includes not only an independent step but also a step that cannot be clearly distinguished from other steps as long as the intended purpose of the step is achieved. A numerical range indicated using “to” indicates a range including numerical values described before and after “to” as a minimum value and a maximum value, respectively. In the numerical range described in stages in the present specification, the upper limit value or the lower limit value of the numerical range in a certain stage may be replaced with the upper limit value or the lower limit value of the numerical range in another stage.

### [Configuration of Thin Wiring Member]

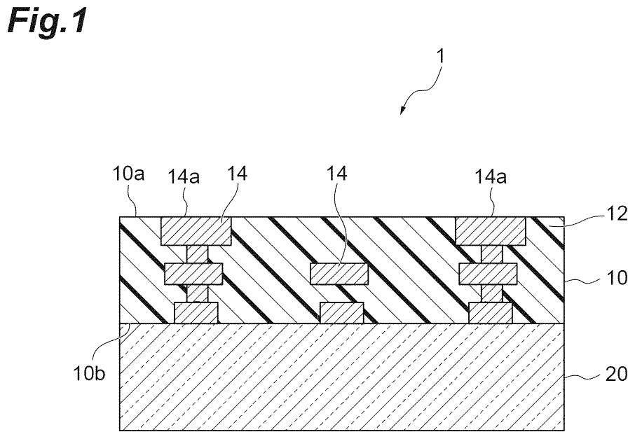

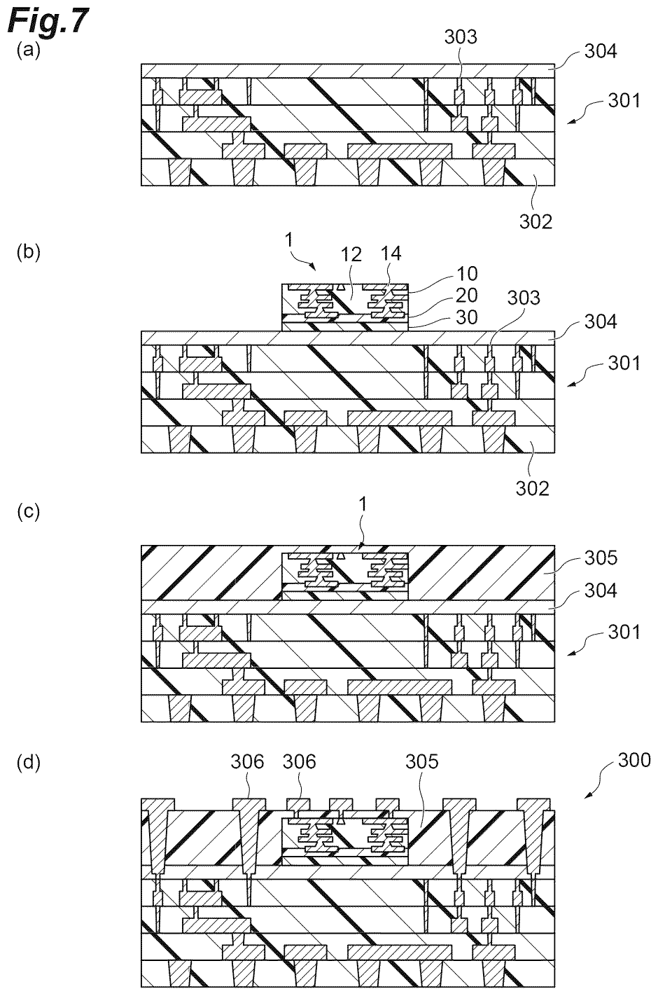

FIG. 1 is a cross-sectional view illustrating an example of a thin wiring member. As illustrated in FIG. 1, a thin wiring member 1 is, for example, a member used for forming a redistribution layer (RDL) of a wiring part of a wiring board 300 described later (see FIG. 7). However, the thin wiring member 1 may be used for wiring or connection thereof in a semiconductor device or the like. The thin wiring member 1 includes a fine wiring layer 10 and a support layer 20. The thin wiring member 1 may further include an adhesive layer 30 (see FIG. 7) for adhering the thin wiring member 1 to a wiring board or the like, and the adhesive layer 30 can be attached to the support layer 20. The adhesive layer 30 can be formed of, for example, an epoxy resin, and can be formed of a die attach film (DAF) or the like. The thin wiring member 1 is a minute wiring member that can be incorporated in various wiring boards, semiconductor devices, or the like, and may have, for example, a rectangular shape of 50 mm long×50 mm wide in plan view, or a rectangular shape of 20 mm long×20 mm wide. The thin wiring member 1 is a thin wiring member, includes a fine wiring layer 10 having a thickness of about 50 μm, and has a total thickness of as thin as, for example, 30 μm to 1 mm. The thickness of the fine wiring layer 10 is, for example, less than or equal to 200 μm. Since the thin wiring member 1 has such a thickness, the thin wiring member 1 has a characteristic of being easily curled and a characteristic of being difficult to handle.

The fine wiring layer 10 is formed by providing a copper wiring 14 (wiring) having a three-dimensional wiring configuration in the insulating layer 12 (insulating part) to form a fine wiring layer. The copper wiring 14 is, for example, a wiring having a fine line width of 0.5 to 5 μm. The copper wiring 14 preferably has a fine line width of 0.7 to 4 μm, and more preferably has a fine line width of 1 to 3 μm. A connection end 14a of the copper wiring 14 is exposed to the outside from a first surface 10a of the fine wiring layer 10. The connection end 14a of the copper wiring 14 is electrically and mechanically connected to the connection terminal. A second surface 10b of the fine wiring layer 10 is adhered and fixed to the first surface 20a of the support layer 20. The copper wiring 14 forms a three-dimensional wiring layer by sequentially stacking the wiring layers from the second surface 10b toward the first surface 10a as described later.

The insulating layer 12 is formed by stacking a plurality of layers, and for example, from the viewpoint of forming fine vias and groove portions, each layer may have a thickness of less than or equal to 10 μm, or may have a thickness of less than or equal to 5 μm. The insulating layer 12 is formed so as to fill the periphery of the copper wiring 14 and exist around the copper wiring 14. On the other hand, in the insulating layer 12, each layer may have a thickness of greater than or equal to 1 μm from the viewpoint of electrical reliability. The insulating layer 12 may have a thickness of 10 to 200 μm or 10 to 100 μm as a whole. Furthermore, the insulating layer 12 may have a coefficient of thermal expansion (after curing) of, for example, less than or equal to 80 ppm/° C. from the viewpoint of preventing warpage. The insulating layer 12 may have a coefficient of thermal expansion (after curing) of, for example, less than or equal to 70 ppm/° C. from the viewpoint of preventing peeling or cracks in the reflow step and the temperature cycle test. On the other hand, the insulating layer 12 may have a coefficient of linear expansion (after curing) of greater than or equal to 20 ppm/° C. from the viewpoint of improving the stress relaxation property to form fine vias or groove portions. The coefficient of linear expansion of the insulating layer 12 may be the same as the coefficient of linear expansion of the support layer 20, or may be smaller or larger than the coefficient of linear expansion of the support layer 20.

The insulating layer 12 is made of, for example, a material such as a polyimide resin, a maleimide resin, an epoxy resin, a phenoxy resin, a polybenzoxazole resin, an acrylic resin, or an acrylate resin. The insulating layer 12 may contain a filler, and the average particle diameter of the contained filler may be less than or equal to 500 nm from the viewpoint of being able to form fine details. The filler may be contained in the insulating layer 12 such that the content of the filler with respect to the total amount of the insulating material is less than 1% by mass. The insulating layer 12 may not contain a filler. The insulating layer 12 is formed of the above-described material, is a layer having adhesiveness and resilience, and is formed as a member having an unstable shape.

The support layer 20 is a layer that supports the fine wiring layer 10 including the insulating layer 12, which is an unstable member, and is made of a material harder than the resin composition of the insulating layer 12 or a cured product thereof. Specifically, the support layer 20 is formed of a material having a bending elastic modulus of greater than or equal to 3 GPa (or a bending strength of greater than or equal to 700 MPa). The support layer 20 can be formed of, for example, a glass carrier. The support layer 20 may be formed from a silicon substrate. The thickness of the support layer 20 may be thinner than the fine wiring layer 10, or conversely, may be thicker than the fine wiring layer 10. The thickness of the support layer 20 may be, for example, 0.3 mm to 1.1 mm. The support layer 20 may be, for example, 25 to 3000% of the thickness of the fine wiring layer 10. The coefficient of thermal expansion of the support layer 20 may be 5 to 50 ppm/° C. Since the support layer 20 has such a coefficient of thermal expansion, warpage or the like can be prevented.

### First Embodiment

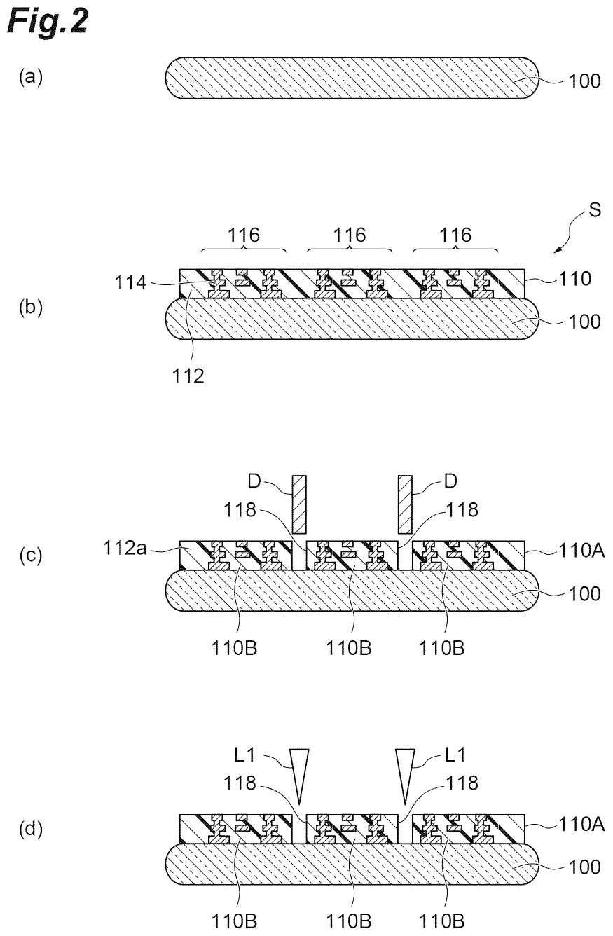

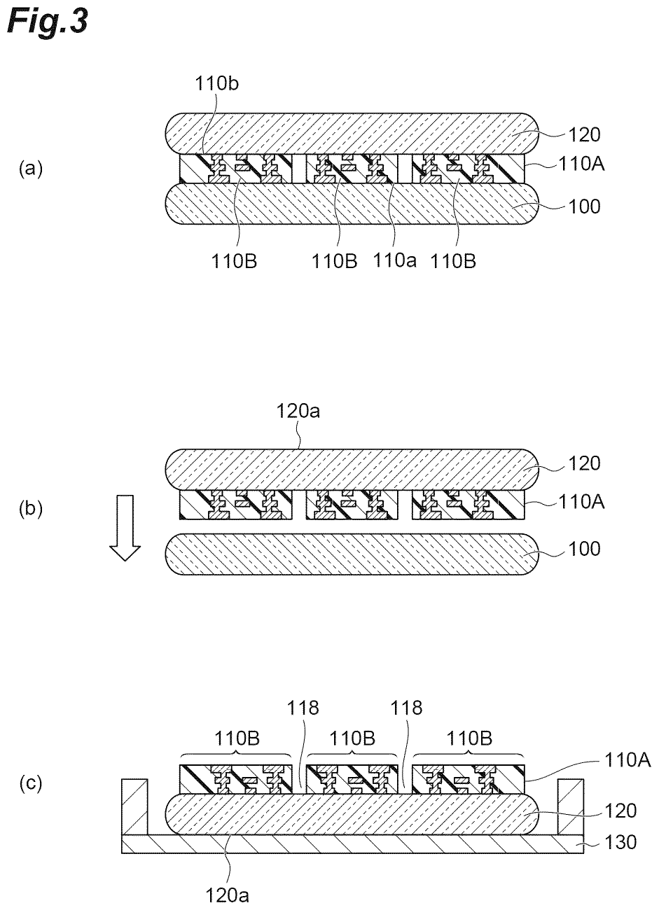

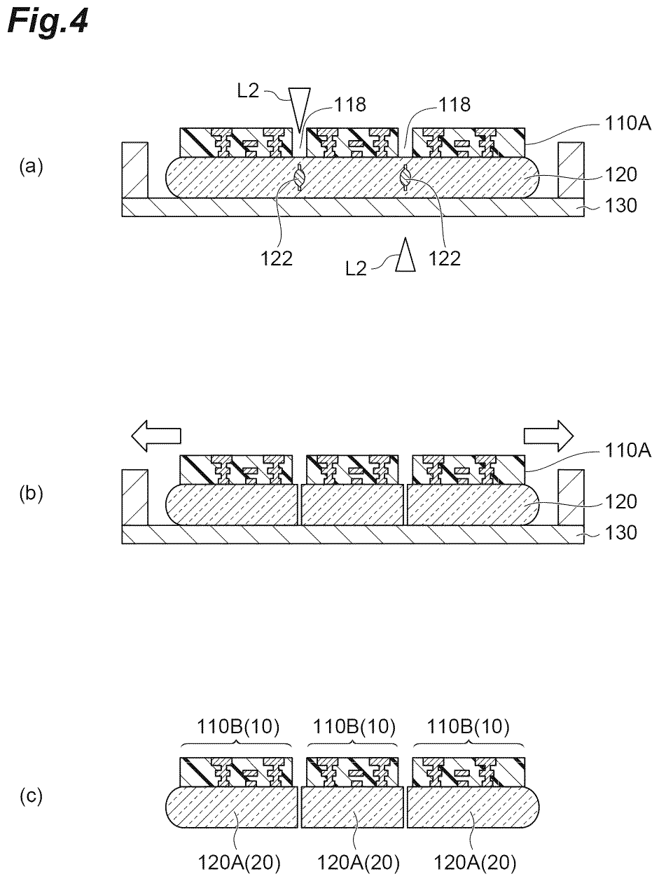

Next, a method for producing a thin wiring member according to the first embodiment will be described with reference to FIG. 2, FIG. 3, and FIG. 4. FIG. 2 to FIG. 4 are views sequentially illustrating a method for producing a thin wiring member illustrated in FIG. 1. As illustrated in (a) of FIG. 2, a first carrier 100 is prepare. The first carrier 100 is, for example, a glass substrate having a thickness of 0.7 mm to 1.1 mm, and has flatness having an arithmetic average roughness of less than or equal to 50 nm. The first carrier 100 has, for example, a wafer shape or a panel shape, and is not particularly limited, but may be, for example, a circular wafer having a diameter of 200 mm, a diameter of 300 mm, or a diameter of 450 mm, or a rectangular panel in which one side is less than or equal to 200 to 700 mm. A temporary fixing material may be attached on the first carrier 100. The temporary fixing material is a resin layer for temporarily fixing an object on the first carrier 100, and is configured such that the object temporarily fixed can be peeled by heating or laser in a later step.

Subsequently, as illustrated in (b) of FIG. 2, the fine wiring layer 110 corresponding to the fine wiring layers 10 is manufactured on the first carrier 100. A method for manufacturing the fine wiring layer 110 is not particularly limited, but a semi-additive process (SAP) or a trench method can be used. In a case of forming the seed layer, there is no particular limitation as long as it is a method capable of forming a metal layer on the surface layer of the first carrier 100, but an electroless plating method or a sputtering method can be used.

In an example of the method for manufacturing the fine wiring layer 110, a metal layer (seed layer) is formed on the first carrier 100. The method for forming the metal layer by electroless plating is not particularly limited, but the surface (e.g., the resin surface of the temporary fixing material) of the first carrier 100 is roughened by desmear or plasma, and the metal layer is formed on the roughened surface. As a method for forming fine wiring with a good yield, a method for forming a metal layer by improving the surface energy of the surface of the first carrier 100 while preventing roughening of the surface by irradiating ultraviolet rays of less than or equal to 200 nm is preferable. As a method for irradiating ultraviolet rays of less than or equal to 200 nm, for example, a low-pressure mercury lamp can be used. As a method for preventing the roughening of the surface, a metal layer can also be formed by sputtering. The seed layer can be easily removed by preventing the roughening of the surface. The thickness of the metal layer to be formed may be less than or equal to 200 nm from the viewpoint of improving the yield at the time of forming the fine wiring.

Subsequently, a resist pattern is formed on the metal layer formed on the first carrier 100. In this resist pattern, the space width of the groove portion is, for example, 0.5 to 5 μm. The resist used for the resist pattern may be either a liquid resist or a film resist. The resist pattern can be formed by exposure with a stepper exposure machine and development with an alkaline aqueous solution.

As a method for forming a via or a groove portion in a resist pattern, laser ablation, photolithography, imprinting, or the like can be used, but a photolithography process can be used from the viewpoint of miniaturization and cost. In this case, a photosensitive resin material can be used as the insulating material. As a method for exposing the photosensitive resin material, a known projection exposure method, contact exposure method, direct drawing exposure method or the like can be used, and as a developing method, an alkaline aqueous solution such as sodium carbonate or TMAH can be used. After the via and the groove portion are formed, the insulating layer may be further heated and cured. The heating may be performed at a heating temperature of 100 to 200° C. for a heating time of 30 minutes to 3 hours.

Subsequently, a wiring part made of copper is formed on the metal layer and in the groove of the resist pattern by electroplating. From the viewpoint of improving the yield at the time of forming fine wiring, the thickness of the metal layer may be less than or equal to 10 μm. Note that when the space width of the resist pattern is 0.5 to 5 μm, the line width of the copper wiring part in the resist pattern formed by electroplating is also 0.5 to 5 μm. After the wiring part made of copper is formed, the resist pattern is peeled and the metal layer is removed. The resist pattern is peeled by a known method. Furthermore, the metal layer is removed using a commercially available etching solution.

By repeating such formation of the wiring layer, a wiring body S in which the fine wiring layer 110 is provided on the first carrier 100 illustrated in (b) of FIG. 2 is formed. (b) of FIG. 2 illustrates an example in which three layers of the wiring 114 are stacked, but the present invention is not limited thereto. The wiring 114 includes a plurality of wiring parts 116 each corresponding to the copper wiring 14 of the thin wiring member 1. The insulating part 112 other than the wiring parts 116 of the fine wiring layer 110 is made of an insulating resin material such as a polyimide resin, a maleimide resin, an epoxy resin, a phenoxy resin, a polybenzoxazole resin, an acrylic resin, or an acrylate resin. The insulating part 112 is formed so as to fill the periphery of each wiring part 116 and exist around each wiring part 116. Such an insulating part 112 has adhesiveness and resilience, and has a configuration in which the shape tends to be unstable. After the fine wiring layer 110 is formed, chemical mechanical polishing (CMP) may be performed in order to planarize the irregularities of the surface.

Subsequently, as illustrated in (c) of FIG. 2, the fine wiring layer 110 supported by the first carrier 100 is cut such that each has at least one wiring part 116 of the plurality of wiring parts 116. In this cutting step, the fine wiring layer 110 is cut with the blade D from the upper surface on the side opposite to the lower surface supported by the first carrier 100 by dicing using a dicer. By cutting with a dicing blade, the fine wiring layer 110 can be efficiently cut even when the cut portion is made of only resin or even when the resin of the cut portion includes a metal layer. Note that by using a dicing blade having a wide processing margin, the fine wiring layer 110 can be reliably cut even when the resin includes the metal layer. The cut fine wiring layer 110A includes a plurality of individual wiring layers 110B each including a wiring part 116 and an insulating part 112a covering the wiring part 116, and the plurality of individual wiring layers 110B are in a state of being divided by each cut region 118. The insulating part 112a is a portion obtained by dividing the insulating part 112. At the time of this dicing, the first carrier 100 or the temporary fixing material on the upper surface thereof may be cut or may be cut so as not to be cut. When there are no cuts or there are few cuts, the first carrier 100 can be reused after the first carrier 100 is peeled in a step to be described later.

Cutting of the fine wiring layer 110 may be performed using a laser beam L1 as illustrated in (d) of FIG. 2. That is, the fine wiring layer 110 supported by the first carrier 100 may be cut by the laser beam L1 such that each has at least one wiring part 116 of the plurality of wiring parts 116, and the cut fine wiring layer 110A may be formed. If the cut portion in the fine wiring layer 110 is only a resin, the fine wiring layer 110 can be accurately cut at a very high speed by using a laser ablation technique. Note that, when the fine wiring layer 110 is cut using the laser beam L1, for example, it is preferable to use an ablation laser. When cutting is performed using the laser beam L1, the surface of the first carrier 100 is less likely to be damaged, so that the first carrier 100 can be easily reused.

Subsequently, when the fine wiring layer 110 is cut to become the fine wiring layer 110A, a second carrier 120 is prepared. Then, as illustrated in (a) of FIG. 3, the second carrier 120 is attached to the upper surface 110b (second surface) on the side opposite to the lower surface 110a (first surface) of the cut fine wiring layer 110A. The second carrier 120 is, for example, a carrier substrate having a thickness of 0.3 mm to 1.1 mm, and may have flatness having an arithmetic average roughness of less than or equal to 50 nm. The second carrier 120 may be thinner than the first carrier 100. The second carrier 120 is preferably a glass substrate, but may be a silicon substrate. The second carrier 120 has, for example, a wafer shape or a panel shape, and is not particularly limited, but may be, for example, a circular wafer having a diameter of 200 mm, a diameter of 300 mm, or a diameter of 450 mm, or a rectangular panel in which one side is less than or equal to 200 to 700 mm.

Subsequently, when the second carrier 120 is attached to the fine wiring layer 110A, the first carrier 100 is peeled from the fine wiring layer 110A as illustrated in (b) of FIG. 3. This peeling may be performed by irradiation with a laser beam, or other methods (e.g., peeling by UV irradiation, peeling by heat treatment, removal (peeling) by a blade, and peeling by immersion in water) may be used. The method for peeling the first carrier 100 is preferably different from the method (mechanism) for peeling the second carrier 120 in a step to be described later, but may be the same method. For example, when the first carrier 100 is peeled using UV irradiation, the second carrier 120 is preferably peeled by a method that creates a trigger for peeling different from the peeling of the first carrier 100, such as heat or a blade. When the first carrier 100 is peeled using a blade or a laser, the second carrier 120 is preferably peeled by a method that creates a trigger for peeling different from peeling of the first carrier 100, such as heat or UV irradiation. By making the peeling method different in this manner, the second carrier 120 can be prevented from peeling when peeling the first carrier 100 from the fine wiring layer 110A.

Subsequently, as illustrated in (c) of FIG. 3, the dicing tape 130 is attached to a surface 120a opposite to a surface to which the fine wiring layer 110A is attached in the second carrier 120 supporting the fine wiring layer 110A with an adhesive film interposed therebetween.

Subsequently, as illustrated in (a) of FIG. 4, the modification region 1220 is formed with the laser beam L2 in an internal region of the second carrier 120 which corresponds to the cut region 118 obtained by cutting the fine wiring layer 110A (stealth dicing). The modification region 122 is a portion modified to serve as a starting point of fracture when the second carrier 120 is expanded (spread) in the planar direction. The laser beam L2 for forming the modification region 122 may be applied from the fine wiring layer 110A side or may be applied from the dicing tape 130 side. Note that as illustrated in (c) or (d) of FIG. 2, when the fine wiring layer 110 is cut with a laser or a blade, a processing trace may remain on the installation surface of the first carrier 100. In this case, in this step, if the modification region 122 is to be formed by the laser beam from the first carrier 100 side, an appropriate modification region may not be formed by the laser beam due to this processing trace. Therefore, by forming the modification region 122 in the second carrier 120 after peeling the first carrier 100, such a formation failure can be prevented, and the modification region 122 can be reliably formed in the second carrier 120.

Subsequently, when the modification region 122 as a starting point of fracture is formed in the second carrier 120, as illustrated in (b) of FIG. 4, the dicing tape 130 is expanded radially outward, and the second carrier 120 is divided similar to the individual wiring layer 110B and divided into individual carrier parts 120A (a plurality of carrier parts). Since the stealth dicing can prevents the occurrence of chipping, cracks, or the like even when the second carrier 120 is thin, it is possible to prevent contamination from occurring at the time of cutting. Since the fine wiring layer 110 having an unstable shape is cut in advance, the fine wiring layer 110 (the individual wiring layer 110B) is not pulled at the time of expanding, and the shape of the individual wiring layer 110B can be reliably maintained.

Thereafter, as illustrated in (c) of FIG. 4, the thin wiring member 1 having the individual wiring layer 110B and the carrier part 120A is obtained. The individual wiring layer 110B corresponds to the fine wiring layer 10 illustrated in FIG. 1, and the carrier part 120A corresponds to the support layer 20 illustrated in FIG. 1. Note that after the thin wiring member 1 is mounted on the wiring board or the like, the carrier part 120A may be peeled from the corresponding individual wiring layer 110B. The method of peeling the carrier part 120A may be, for example, peeling by laser irradiation, and is preferably different from the method of peeling the first carrier 100 from the fine wiring layer 110A. However, the method of peeling the carrier part 120A and the method of peeling the first carrier 100 may be the same.

As described above, the method for producing a thin wiring member according to the present embodiment includes, apart from the step of cutting the fine wiring layer 110, the steps of: forming, with laser beam L2, a modification region 122 to become a starting point of a fracture, in an internal region of the second carrier 120 which corresponds to the cut region 118 obtained by cutting the fine wiring layer 110A; and expanding the second carrier 120 on which the modification region 122 is formed along the planar direction to divide the second carrier 120 into the plurality of carrier parts 120A. In this method, instead of using a dicing blade when dividing the second carrier 120, a fracture origin is formed by laser beam, and the second carrier 120 is fractured from the fracture origin when expanding. This is laser dicing processing referred to as so-called stealth dicing, and by using such a processing method, it is possible to prevent cracks and chipping from occurring in the divided second carrier 120. This makes it possible to manufacture the thin wiring member 1 while preventing the occurrence of contamination. In addition, according to the method for producing a thin wiring member, since cracks and chipping do not occur when the second carrier 120 is divided, decrease in the strength of the carrier can be prevented. Furthermore, according to the method for producing a thin wiring member, since cracks and chipping do not occur when the second carrier 120 is divided, damage to the wiring part 116 in the thin wiring member 1 can be prevented.

In the method for producing a thin wiring member according to the present embodiment, when cutting the fine wiring layer 110, the fine wiring layer 110 is cut with a laser or a dicing blade. The fine wiring layer 110 to be cut is a member having an unstable shape, which is formed of a thin material having a thickness of, for example, 10 to 50 μm and having adhesiveness or resilience. However, when the fine wiring layer 110 is cut using a laser, if the cut portion is only a resin, the fine wiring layer 110 can be accurately cut at a very high speed by using a laser ablation technique. On the other hand, when the metal layer is included in the resin of the cut portion, the wiring layer can be efficiently cut even if the metal layer is included in the resin by using the dicing blade having a wide processing margin.

In the method for producing a thin wiring member according to the present embodiment, cutting is performed in a state where the fine wiring layer 110 is disposed on the first carrier 100. As described above, the fine wiring layer 110 to be cut is a member having an unstable shape. However, by cutting the fine wiring layer 110 in a state of being supported on the first carrier 100, the fine wiring layer 110 can be cut with high accuracy.

In the method for producing a thin wiring member according to the present embodiment, the fine wiring layer 110 may be cut by an ablation laser, and the peeled first carrier 100 may be collected for reuse. In this case, it is possible to prevent the first carrier 100 from being damaged or hardly damaged when cutting the fine wiring layer 110. As a result, according to this production method, the first carrier 100 used for manufacturing the redistribution layer can be reused, and the load on the environment can be reduced.

In the method for producing a thin wiring member according to the present embodiment, the modification region 121 is formed after the first carrier 100 is peeled off. When the fine wiring layer 110 is cut with a laser or a blade, a processing trace may remain on the installation surface of the first carrier 100. In this case, if an attempt is made to form the modification region with the laser beam from the first carrier 100 side, an appropriate modification region may not be formed with the laser beam due to this processing trace. Therefore, by forming the modification region 122 in the second carrier 120 after peeling the first carrier 100, such a manufacturing failure can be prevented, and the modification region can be reliably formed in the second carrier 120.

In the method for producing a thin wiring member according to the present embodiment, the method for peeling the first carrier 100 from the fine wiring layer 110A may be different from the mechanism for peeling the second carrier 120 or the carrier part 120A. As a result, when peeling the first carrier 100, the second carrier 120 necessary for the subsequent steps can be prevented from being peeled off, and the thin wiring member 1 can be more reliably manufactured. In addition, since the peeling method is different, the first carrier 100 can be easily peeled.

In the method for producing a thin wiring member according to the present embodiment, the second carrier 120 may be a glass carrier having a thickness of 0.3 mm to 1.1 mm. In this case, the degree of freedom of the production method when forming the modification region can be increased. In addition, it is easier to perform laser irradiation or the like when peeling the carrier part 120A from the individual wiring layer 110B after using the thin wiring member 1 as a member.

In the method for producing a thin wiring member according to the present embodiment, the dicing tape 130 is attached to the surface 120a opposite to the surface to which the fine wiring layer 110 is attached in the second carrier 120. When the second carrier 120 is divided, the second carrier 120 is expanded by spreading the dicing tape 130. As a result, the second carrier 120 on which the modification region 122 is formed can be easily divided by a simple means.

### Second Embodiment

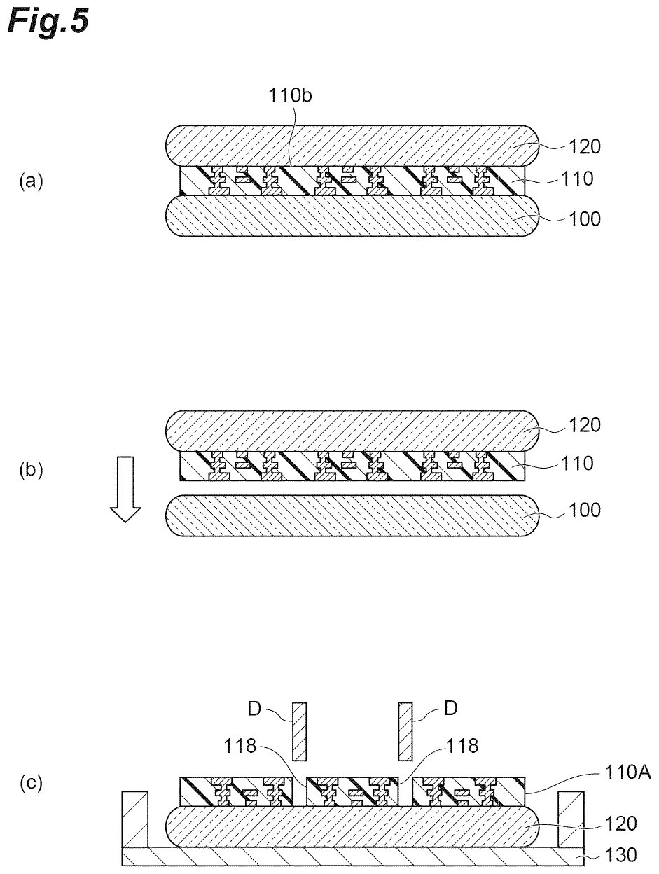

Next, a method for producing a thin wiring member 1 according to a second embodiment will be described with reference to FIG. 5. FIG. 5 are views sequentially illustrating a method for producing a thin wiring member according to the second embodiment. Hereinafter, differences from the production method according to the first embodiment will be mainly described, and description of the same parts may be omitted. In the method for producing a thin wiring member according to the second embodiment, as in the first embodiment, a first carrier 100 is prepared as illustrated in (a) of FIG. 2. Then, as illustrated in (b) of FIG. 2, the fine wiring layer 110 is formed on the first carrier 100.

Subsequently, when the fine wiring layer 110 is formed, as illustrated in (a) of FIG. 5, the second carrier 120 is attached to the upper surface 110b of the fine wiring layer 110. In the production method according to the second embodiment, unlike the first embodiment, the second carrier 120 is attached before the fine wiring layer 110 is cut.

Subsequently, as illustrated in (b) of FIG. 5, the first carrier 100 is peeled from the fine wiring layer 110. A method of peeling the first carrier 100 is similar to that of the first embodiment.

Subsequently, as illustrated in (c) of FIG. 5, the second carrier 120 supporting the fine wiring layer 110 is attached to the dicing tape 130 via the adhesive film. Then, the fine wiring layer 110 supported by the second carrier 120 is cut such that each has at least one wiring part 116 of the plurality of wiring parts 116. The cutting method may be cutting by dicing using the blade D as in the first embodiment, or may be cutting using the laser beam L1.

After the fine wiring layer 110 is cut to form the individual wiring layer 110B, similarly to the first embodiment, a modification region 122 is formed with the laser beam L2 in an internal region of the second carrier 120 which corresponds to the cut region 118 obtained by cutting the fine wiring layer 110A (see (a) of FIG. 4). Then, as illustrated in (b) of FIG. 4, the dicing tape 130 is expanded radially outward, and the second carrier 120 is divided and divided into individual carrier parts 120A in the same manner as the individual wiring layer 110B. Thus, a plurality of thin wiring members 1 are obtained.

As described above, similarly to the first embodiment, the method for producing a thin wiring member according to the second embodiment includes, apart from the step of cutting the fine wiring layer 110, the steps of forming, with laser beam L2, a modification region 122 to become a starting point of a fracture, in an internal region of the second carrier 120 which corresponds to the cut region 118 obtained by cutting the fine wiring layer 110A; and expanding the second carrier 120 on which the modification region 122 is formed along the planar direction to divide the second carrier 120 into the plurality of carrier parts 120A. As a result, according to the present embodiment, cracks and chipping can be prevented from occurring in the divided second carrier 120, and the thin wiring member 1 can be manufactured while preventing the occurrence of contamination. In addition, according to the method for producing a thin wiring member, since cracks and chipping do not occur when the second carrier 120 is divided, decrease in the strength of the carrier can be prevented. Furthermore, according to the method for producing a thin wiring member, since cracks and chipping do not occur when the second carrier 120 is divided, damage to the wiring part 116 in the thin wiring member 1 can be prevented.

In the method for producing a thin wiring member according to the present embodiment, the fine wiring layer 110 is cut after the second carrier 120 is attached to the fine wiring layer 110. Therefore, it is possible to prevent the first carrier 100 from being peeled and damaged when the fine wiring layer 110 is cut. As a result, according to this production method, the first carrier 100 used for manufacturing the redistribution layer can be reused, and the load on the environment can be reduced.

### Third Embodiment

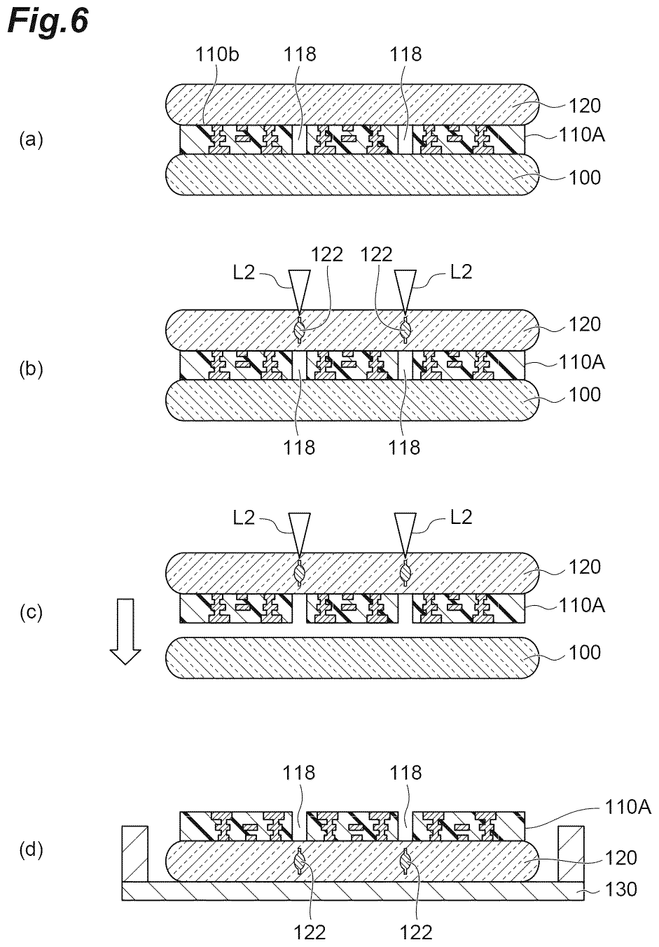

Next, a method for producing the thin wiring member 1 according to a third embodiment will be described with reference to FIG. 6. FIG. 6 are views sequentially illustrating a method for producing a thin wiring member according to the third embodiment. Hereinafter, differences from the production method according to the first embodiment will be mainly described, and description of the same parts may be omitted.

In the method for producing a thin wiring member according to the third embodiment, as in the first embodiment, a first carrier 100 is prepared as illustrated in (a) of FIG. 2. Then, as illustrated in (b) of FIG. 2, the fine wiring layer 110 is formed on the first carrier 100, and as illustrated in (c) of FIG. 2, the fine wiring layer 110 supported by the first carrier 100 is cut by a dicing blade using a blade D to obtain a fine wiring layer 110A having a plurality of individual wiring layers 110B. The cutting may be performed by the laser beam L1 as in the first embodiment.

Subsequently, as illustrated in (a) of FIG. 6, the second carrier 120 is attached to the upper surface 110b of the cut fine wiring layer 110A.

Subsequently, as illustrated in (b) of FIG. 6, the modification region 122 is formed with the laser beam L2 in an internal region of the second carrier 120 attached to the fine wiring layer 110A corresponding to the cut region 118 obtained by cutting the fine wiring layer 110A. At this time, the irradiation of the laser beam L2 for forming the modification region 122 is performed from the upper surface of the second carrier 120 toward the fine wiring layer 110A.

Subsequently, as illustrated in (c) of FIG. 6, the first carrier 100 is peeled from the cut fine wiring layer 110A. This peeling may be performed by irradiation with the laser beam L2 or the like. When the first carrier 100 is peeled, if the second carrier 120 is bent, cracks may form with the modification region 122 as a starting point since the modification region 122 is already formed in the second carrier 120. Therefore, in this production method, when the first carrier 100 is peeled so that cracks are not formed in the second carrier 120 at this stage, it is preferable to bend and peel the first carrier 100 without bending the second carrier 120. Thereafter, as illustrated in (d) of FIG. 6, the second carrier 120 supporting the fine wiring layer 110A is attached to the dicing tape 130 via the adhesive film. Then, as illustrated in (b) of FIG. 4, the dicing tape 130 is expanded radially outward, and the second carrier 120 is individualized and divided into individual carrier parts 120A in the same manner as the individual wiring layer 110B. Thus, a plurality of thin wiring members 1 are obtained.

As described above, similarly to the first embodiment and the second embodiment, the method for producing a thin wiring member according to the third embodiment includes, apart from the step of cutting the fine wiring layer 110, the steps of forming, with laser beam L2, a modification region 122 to become a starting point of a fracture, in an internal region of the second carrier 120 which corresponds to the cut region 118 obtained by cutting the fine wiring layer 110A; and expanding the second carrier 120 on which the modification region 122 is formed along the planar direction to divide the second carrier 120 into the plurality of carrier parts 120A. As a result, according to the present embodiment, cracks and chipping can be prevented from occurring in the divided second carrier 120, and the thin wiring member 1 can be manufactured while preventing the occurrence of contamination. In addition, according to the method for producing a thin wiring member, since cracks and chipping do not occur when the second carrier 120 is divided, decrease in the strength of the carrier can be prevented. Furthermore, according to the method for producing a thin wiring member, since cracks and chipping do not occur when the second carrier 120 is divided, damage to the wiring part 116 in the thin wiring member 1 can be prevented.

In the method for producing a thin wiring member according to the present embodiment, the modification region 122 is formed before the first carrier 100 is peeled.

### [Method for Producing Wiring Board]

Next, an example of a method for producing a wiring board using the above-described thin wiring member 1 will be described with reference to FIG. 7. FIG. 7 are views sequentially showing an example of a method for producing a wiring board using a thin wiring member. In this method for producing a wiring board, the thin wiring member 1 is prepared, and a substrate main body 301 is prepared. As illustrated in (a) of FIG. 7, the substrate main body 301 is a member in which insulating layers 302 and wiring layers 303 are alternately stacked. The substrate main body 301 is provided with an installation layer 304 for disposing the thin wiring member 1.

Subsequently, when the preparation of the thin wiring member 1 and the like is completed, the thin wiring member 1 is mounted on the installation layer 304 of the substrate main body 301 as illustrated in (b) of FIG. 7. At this time, the thin wiring member 1 is attached to the installation layer 304 via the adhesive layer 30 or the like. Note that the thin wiring member 1 may be mounted on the inner side of the substrate main body 301.

Subsequently, as illustrated in (c) of FIG. 7, an insulating resin portion 305 is formed on the installation layer 304 of the substrate main body 301 on which the thin wiring member 1 is mounted. The insulating resin portion 305 is patterned to form a wiring 306. Thereafter, a connection terminal is further provided and connected to the wiring of the thin wiring member 1. The wiring board 300 can be obtained as described above.

Although the method for producing a thin wiring member, the thin wiring member, and the method for producing a wiring board according to embodiments of the present disclosure have been described above, the present disclosure is not limited to the above-described embodiments, and can be appropriately changed without departing from the gist thereof.

### REFERENCE SIGNS LIST

1 thin wiring member

10 fine wiring layer
20 support layer
100 first carrier
110 fine wiring layer (wiring layer)
110A fine wiring layer
110B Individual wiring layer
110a lower surface (first surface)
110b upper surface (second surface)
112 insulating part
114 wiring
116 wiring part
118 cut region
120 second carrier
120A carrier part
120a surface
122 modification region
130 dicing tape
D blade
L1, L2 laser beam

1. A method for producing a thin wiring member, the method comprising:
forming a wiring layer on a first carrier, the wiring layer including a plurality of wiring parts corresponding to each thin wiring member and an insulating part existing around the plurality of wiring parts;
cutting the wiring layer such that each includes at least one wiring part of the plurality of wiring parts;
attaching a second carrier to a second surface on opposite side of a first surface on which the first carrier is provided in the wiring layer;
peeling the first carrier from the wiring layer,
forming, with laser beam, a modification region to become a starting point of a fracture, in an internal region of the second carrier which corresponds to a site at which the wiring layer has been cut; and
expanding the second carrier on which the modification region is formed along a planar direction to divide the second carrier into a plurality of carrier parts.

2. The method for producing a thin wiring member according to claim 1, wherein the cutting includes cutting the wiring layer with a laser or a dicing blade.

3. The method for producing a thin wiring member according to claim 1, wherein the cutting is performed in a state where the wiring layer is supported by the first carrier.

4. The method for producing a thin wiring member according to claim 3, wherein
the cutting includes cutting the wiring layer by an ablation laser, and
the peeling includes collecting the peeled first carrier for reuse.

5. The method for producing a thin wiring member according to claim 1, wherein the cutting is performed after the second carrier is attached to the wiring layer.

6. The method for producing a thin wiring member according to claim 1, wherein the forming of the modification region is performed after the peeling the first carrier.

7. The method for producing a thin wiring member according to claim 1, wherein the forming of the modification region is performed before peeling the first carrier.

8. The method for producing a thin wiring member according to claim 1, wherein a method to peel the first carrier from the wiring layer is different from a mechanism in which the second carrier or the carrier part is peeled.

9. The method for producing a thin wiring member according to claim 1, wherein the second carrier is a glass carrier having a thickness of 0.3 mm to 1.1 mm.

10. The method for producing a thin wiring member according to claim 1, wherein the second carrier is a silicon substrate.

11. The method for producing a thin wiring member according to claim 1, further comprising
attaching a dicing tape to a surface of the second carrier opposite to a surface to which the wiring layer is attached, wherein the dividing includes expanding the second carrier by spreading the dicing tape.

12. A thin wiring member comprising:
a wiring layer including a wiring and a resin composition present around the wiring or a cured product thereof; and
a support layer provided on a surface of the wiring layer, wherein the support layer is a glass carrier.

13. The thin wiring member according to claim 12, wherein
a thickness of the wiring layer is less than or equal to 200 μm,
a thickness of the support layer is 0.3 mm to 1.1 mm, and
the wiring layer includes wiring having a line width of 5 μm or less.

14. A method for producing a wiring board, comprising:
preparing a thin wiring member produced by the method for producing a thin wiring member according to claim 1;
arranging the thin wiring member on a substrate or in the substrate; and
connecting the wiring of the thin wiring member to a connection terminal.
